(19) United States
(12) Patent Application Publication
(10) Pub. No.: US 2015/0069357 A1
(43) Pub. Date: Mar. 12, 2015

(54) DISPLAY DEVICE

(71) Applicant: SAMSUNG DISPLAY CO., LTD., Yongin-City (KR)

(72) Inventor: Mie Hwa PARK, Yongin-City (KR)

(21) Appl. No.: 14/464,980

(22) Filed: Aug. 21, 2014

(30) Foreign Application Priority Data
Sep. 6, 2013 (KR) 10-2013-0107336

(51) Int. Cl. H01L 27/32; H01L 51/00; H01L 51/50

(52) U.S. Cl. CPC H01L 27/32; H01L 51/5012; H01L 51/508; H01L 51/5092; H01L 51/0054; H01L 51/0067; H01L 51/0052; H01L 51/5056; H01L 51/5088
USPC 257/40

(57) ABSTRACT

A display device is provided that may include a first electrode, an organic light emitting layer positioned on the first electrode, a second electrode positioned on the organic light emitting layer, and an electron transport layer interposed between the organic light emitting layer and the second electrode, and including an electron transport material and an electron injection material. One side portion of the electron transport layer that is adjacent to the organic light emitting layer may include a greater amount of the electron injection material than the electron transport material.

### CROSS-REFERENCE TO RELATED APPLICATION

Korean Patent Application No. 10-2013-0107336, filed on Sep. 6, 2013, in the Korean Intellectual Property Office, and entitled: “Display Device,” which is incorporated by reference herein in its entirety.

### BACKGROUND

1. Field

Embodiments are directed to a display device.

2. Description of the Related Art

Display devices may include a liquid crystal display, an electrophoretic display panel, an organic light emitting display, an electroluminescent display, a FED (Field Emission Display), an SED (Surface-conduction Electron-emitter Display), a plasma display, or a CRT (Cathode Ray Tube) display.

### SUMMARY

A display device according to exemplary embodiments may include a first electrode, an organic light emitting layer on the first electrode, a second electrode on the organic light emitting layer, and an electron transport layer between the organic light emitting layer and the second electrode, and including an electron transport material and an electron injection material. One side portion of the electron transport layer that is adjacent to the organic light emitting layer may include a greater amount of the electron injection material than the electron transport material.

An other side portion of the electron transport layer that faces the one side portion of the electron transport layer may include a greater amount of the electron transport material than the electron injection material.

The electron transport material may include at least one of a pyrene series material, a triazine series material, and an anthracene series material, and the electron injection material may include at least one of LiF, LiQ, and NaQ.

The display device may also include an electron injection layer between the electron transport layer and the second electrode. The electron injection layer may include the electron injection material.

The electron transport layer may include a first electron transport layer that is adjacent to the organic light emitting layer and a second electron transport layer on the first electron transport layer. A volume ratio between the electron transport material and the electron injection material in the first electron transport layer may range from about 1:9 to about 5:5, and a volume ratio between the electron transport material and the electron injection material in the second electron transport layer may range from about 5:5 to about 9:1.

The electron transport layer may include an intermediate layer between the first electron transport layer and the second electron transport layer, and a ratio of the electron injection material to the electron transport material in the intermediate layer may increase in a direction towards the organic light emitting layer.

The electron transport layer may include a first electron transport layer that is adjacent to the organic light emitting layer, a second electron transport layer on the first electron transport layer, and a third transport layer on the second electron transport layer. A volume ratio between the electron transport material and the electron injection material in the first electron transport layer may range from about 1:9 to about 3:7, a volume ratio between the electron transport material and the electron injection material in the second electron transport layer may range from about 3:7 to about 7:3, and a volume ratio between the electron transport material and the electron injection material in the third electron transport layer may range from about 7:3 to 9:1.

A ratio of the electron injection material to the electron transport material in the electron transport layer may increase in a direction towards the organic light emitting layer.

The organic light emitting layer may include a first organic light emitting layer and a second organic light emitting layer on the first organic light emitting layer, the electron transport layer may include a first electron transport layer on the first organic light emitting layer and a second electron transport layer on the second organic light emitting layer, and one side portion of the first electron transport layer that is adjacent to the first organic light emitting layer and one side portion of the second electron transport layer that is adjacent to the second organic light emitting layer may each include a greater amount of the electron injection material than the electron transport material.

The display device according to exemplary embodiments may also include a charge generation layer between the first electron transport layer and the second organic light emitting layer.

The electron transport layer may be formed by vacuum-depositing the electron transport material and the electron injection material.

A display device according to exemplary embodiments may include a first electrode, an organic light emitting layer on the first electrode, a second electrode on the organic light emitting layer, and a hole transport layer between the first electrode and the organic light emitting layer, and including a hole transport material and a hole injection material. One side portion of the hole transport layer that is adjacent to the organic light emitting layer may include a greater amount of the hole injection material than the hole transport material.

An other side portion of the hole transport layer that faces the one side portion of the hole transport layer may include a greater amount of the hole transport material than the hole injection material.

The display device according to exemplary embodiments may also include a hole injection layer between the first electrode and the hole transport layer. The hole injection layer may also include the hole injection material.

A ratio of the hole injection material to the hole transport material in the hole transport layer may increase in a direction towards the organic light emitting layer.

A display device according to exemplary embodiments may include a substrate including a first region and a second region, a hole transport layer on the substrate, and an electron transport layer on the hole transport layer. The electron transport layer may include an electron transport material and an electron injection material, and a portion of the electron transport layer that is adjacent to the hole transport layer may include a greater amount of the electron injection material than the electron transport material. The hole transport layer and the electron transport layer may cover an entire surface of the substrate, and the hole transport layer and the electron transport layer may be in direct contact with each other in the second region and may not be in direct contact with each other in the first region.

A portion of the electron transport layer which faces the portion that is adjacent to the hole transport layer may include a greater amount of the electron transport material than the electron injection material.

A display device according to exemplary embodiments may include an organic light emitting layer in the first region between the hole transport layer and the electron transport layer.

A display device according to exemplary embodiments may include a pixel-defining film in the second region between the substrate and the hole transport layer.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a display device according to an embodiment;

FIG. 2 illustrates an enlarged cross-sectional view of an upper portion (A portion) of a first region of the display device of FIG. 1;

FIG. 3 illustrates an enlarged cross-sectional view of an upper portion (B portion) of a second region of the display device of FIG. 1;

FIG. 4 illustrates an enlarged cross-sectional view of an upper portion of a first region of a display device according to another embodiment;

FIG. 5 illustrates an enlarged cross-sectional view of an upper portion of a second region of the display device of FIG. 4;

FIG. 6 illustrates an enlarged cross-sectional view of an upper portion of a first region of a display device according to still another embodiment;

FIG. 7 illustrates an enlarged cross-sectional view of an upper portion of a second region of the display device of FIG. 6;

FIG. 8 illustrates an enlarged cross-sectional view of an upper portion of a first region of a display device according to still another embodiment;

FIG. 9 illustrates an enlarged cross-sectional view of an upper portion of a second region of the display device of FIG. 8;

FIG. 10 illustrates an enlarged cross-sectional view of an upper portion of a first region of a display device according to still another embodiment;

FIG. 11 illustrates an enlarged cross-sectional view of an upper portion of a second region of the display device of FIG. 10; and

FIG. 12 illustrates an enlarged cross-sectional view of an upper portion of a first region of a display device according to still another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

In some embodiments, well-known structures and devices are not shown in order not to obscure the description of the exemplary embodiments with unnecessary detail.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. It will also be understood that when a layer is referred to as being “between” two layers, it can be the only layer between the two layers, or one or more intervening layers may also be present. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described referring to plan views and/or cross-sectional views by way of ideal schematic views of exemplary embodiments. Accordingly, the exemplary views may be modified depending on manufacturing technologies and/or tolerances. Therefore, the exemplary embodiments are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of exemplary embodiments.

A “display device” that is described in the description may be one of various display devices. In an exemplary embodiment, the display device described in the description may be any one of a liquid crystal display, an electrophoretic display panel, an organic light emitting display, an electroluminescent display, a FED (Field Emission Display), an SED (Surface-conduction Electron-emitter Display), a plasma display, and a CRT (Cathode Ray Tube) display, but is not limited thereto. Hereinafter, an organic light emitting display is described as an example of the display device according to exemplary embodiments. However, the display device according to exemplary embodiments is not limited thereto, and various kinds of display devices may be used.

Hereinafter, embodiments will be described with reference to the accompanying drawings.

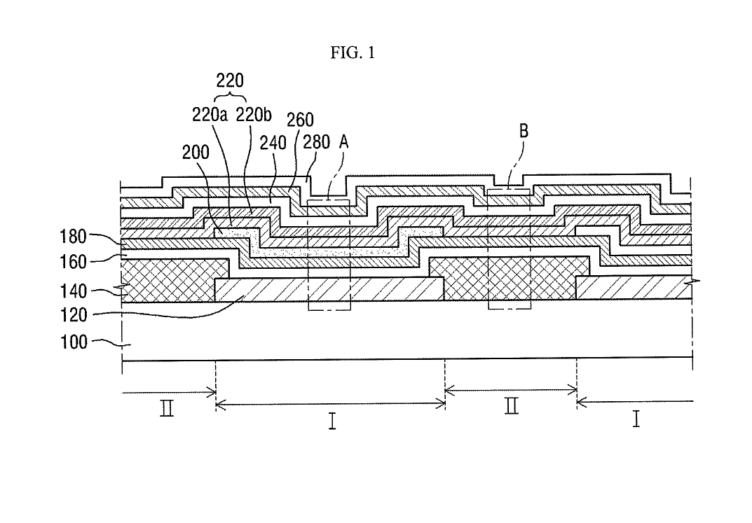

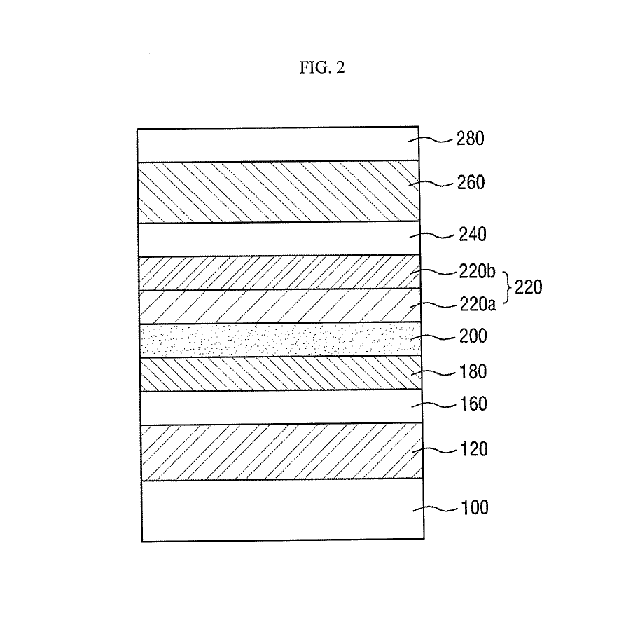

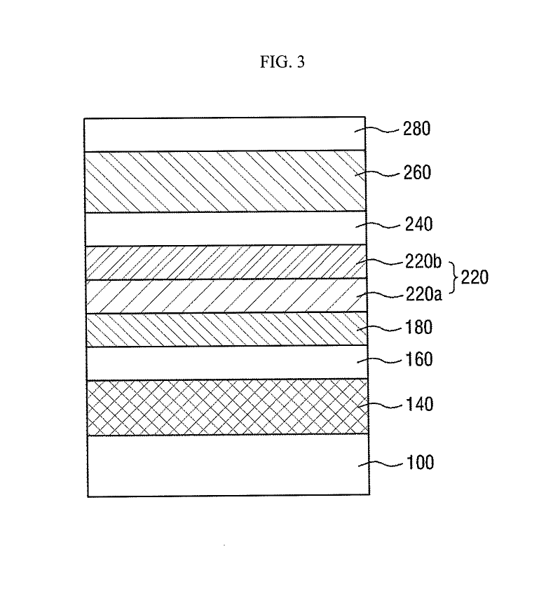

FIG. 1 illustrates a cross-sectional view of a display device according to an embodiment. FIG. 2 illustrates an enlarged cross-sectional view of an upper portion (A portion) of a first region I of the display device of FIG. 1, and FIG. 3 illustrates an enlarged cross-sectional view of an upper portion (B portion) of a second region II of the display device of FIG. 1. Referring to FIGS. 1 to 3, a display device according to an embodiment may include a substrate 100, a first electrode 120, a pixel-defining film 140, a hole injection layer 160, a hole transport layer 180, an organic light emitting layer 200, an electron transport layer 220, an electron injection layer 240, a second electrode 260, and a cover layer 280.

The substrate 100 may include an insulating substrate. The insulating substrate may be formed of a transparent glass material having SiO₂ as a main component. In some embodiments, the insulating substrate may be made of an opaque material.

The substrate 100 may include a flexible substrate that can change shape, such as rolling, folding, and bending. The flexible substrate may be made of a plastic material having superior heat resistance and durability, such as polyarylate, polyetherimide, polyethersulfone, or polyimide. However, embodiments are not limited thereto, and various flexible materials may be used.

Although not illustrated in the drawing, the substrate 100 may further include other structures formed on the insulating substrate. Examples of other structures may be a wiring, an electrode, an insulating film, and the like. In the case where the display device according to this embodiment is an active organic light emitting display, the substrate 100 may include a plurality of thin film transistors that are formed on the insulating substrate. The thin film transistor may include a gate electrode, a source electrode, a drain electrode, and a semiconductor layer that is a channel region. The semiconductor layer may be formed of amorphous silicon, fine crystalline silicon, polycrystalline silicon, or monocrystalline silicon. In alternative embodiments, the semiconductor layer may be made of oxide semiconductor. The drain electrode of at least a part of the plurality of thin film transistors may be electrically connected to the first electrode 120.

The substrate 100 may include a plurality of regions. Such a plurality of regions may include a first region I and a second region II. In an exemplary embodiment, the first region I may be a light emitting region that emits light in the display device, and the second region II may be a non-light emitting region that does not emit light in the display device. In another exemplary embodiment, the first region I may be a region in which the first electrode 120 is positioned, and the second region II may be a region in which the pixel-defining film 140 is positioned. In still another exemplary embodiment, the first region I may be a region in which the organic light emitting layer 200 is positioned, and the second region II may be a region in which the organic light emitting layer 200 is not positioned. In still another exemplary embodiment, the first region I may be a region in which the hole transport layer 180 and the electron transport layer 220 do not mutually come in direct contact with each other, and the second region II may be a region in which the hole transport layer 180 and the electron transport layer 220 mutually come in direct contact with each other. Although not illustrated in the drawing, on a plan view, the second region II may have a lattice shape, and the first region I may be a region surrounded by the second region II.

The first electrode 120 may be positioned on the substrate 100. In an exemplary embodiment, the first electrode 120 may be positioned on the first region I of the substrate 100. The first electrode 120 may be formed to come in direct contact with the substrate 100, or a material, such as an insulating film, and may be interposed between the first electrode 120 and the substrate 100.

The first electrode 120 may be an anode electrode or a cathode electrode. If the first electrode 120 is an anode electrode, the second electrode 260 is a cathode electrode. Hereinafter, embodiments will be described with a first electrode 120 as an anode electrode. However, the first electrode 120 may also be a cathode electrode, and the second electrode 260 may be an anode electrode.

The first electrode 120 that is used as an anode electrode may be made of a conductive material having high work function. In the case where the organic light emitting display is a bottom emission display device, the first electrode 120 may be formed of ITO, IZO, ZnO, In₂O₃, or a laminated film thereof. In the case where the organic light emitting display is a top emission display device, the first electrode may further include a reflective film that is formed of Ag, Mg, Al, Pt, Pd, Au, Ni, Nd, Ir, Cr, Li, Ca, or a combination thereof. The first electrode 120 may include various modifications, such as a two or more layer structure using two or more of the above-described materials.

The pixel-defining film 140 may be positioned on the substrate 100. In an exemplary embodiment, the pixel-defining film 140 may be positioned on the second region II of the substrate 100. Further, the pixel-defining film 140 may be formed to make direct contact with the substrate 100, or a material, such as an insulating film, and may be interposed between the pixel-defining film 140 and the substrate 100. Further, the pixel-defining film 140 may include an opening for exposing a region in which a pixel is to be formed. The opening may be positioned on the first region I. Further, the pixel-defining film 140 may be thicker than the first electrode 120.

The pixel-defining film 140 may include at least one organic material selected from the group including benzo cyclo butene (BCB), polyimide (PI), poly amaide (PA), acrylic resin, and phenol resin, or may include an inorganic material, such as silicon nitride.

The hole injection layer 160 may be positioned on the first electrode 120 and the pixel-defining film 140. That is, the hole injection layer 160 may be separated by pixels, or may be formed to cover the whole surface of the substrate 100 as illustrated in FIG. 1. The hole injection layer 160 may be a common layer that is commonly formed on the first region I and the second region II. In some embodiments, the hole injection layer 160 may be omitted.

The hole injection layer 160 may include a hole injection material. The hole injection material may be selected from known hole injection materials. For example, the hole injection material may include TCTA or m-MTDATA, which is a phthalocyanine compound, such as copper phthalocyanine, or starburst amine derivatives, Pani/DBSA (Polyaniline/Dodecylbenzenesulfonic acid) or PEDOT/PSS (Poly(3,4-ethylenedioxythiophene)/Poly(4-styrenesulfonate)), which is a conductive polymer, Pani/CSA (Polyaniline Camphor sulfonic acid), or PANI/PSS (Polyaniline)/Poly(4-styrent-sulfonate), but the hole injection material is not limited thereto.

The hole transport layer 180 may be positioned on the hole injection layer 160. That is, the hole transport layer 180 may be separated by pixels, or as illustrated in FIG. 1, may be formed to cover the whole surface of the substrate 100. That is, the hole transport layer 180 may be a common layer that is commonly formed in the first region I and the second region II.

The hole transport layer 180 may include a hole transport material. The hole transport layer 180 may be selected from known hole transport materials. For example, the hole transport material may include 1,3,5-tri(carbazolyl)benzene, 4,4′-bis(carbazolyl)biphenyl, polyvinylcarbazol, m-bis(carbazolyl)phenyl, 4,4′-bis(carbazolyl)-2,2′-dimethylbiphenyl, 4,4′,4″-tri(N-carbazolyl)triphenylamine,
1,3,5-tri(2-carbazolylphenyl)benzene, 1,3,5-tris(2-carbazolyl-5-methoxyphenyl)benzene, bis(4-carbazolylphenyl)silane, N,N′-bis(3-methyphenyl)-N,N′-diphenyl-[1,1-biphenyl]-4,4′ diamine (TPD), N,N′-di(naphthalene-1-i1)-N,N′-dephenylbenzidine (NPD), N,N′-diphenyl-N,N′-bis(1-naphthyl)-(1,1′-biphenyl)-4,4′-diamine (NPB), poly(9,9-dioctylfluorene-co-N-(4-buthylphenyl)diphenylamine) (TFB), or poly(9,9-dioctylfluorene-co-bis-(4-buthylphenyl)-bis-N,N-phenyl-1,4-phenylenediamine) (PFB), but is not limited thereto.

The hole injection layer 160 or the hole transport layer 180 may be formed using various methods, such as a vacuum deposition method, a spin coating method, a cast method, and an LB method. In the case where the hole injection layer 160 or the hole transport layer 180 is formed by a vacuum deposition method, the deposition conditions may differ depending on the compounds used as materials of the hole injection layer 160 or the hole transport layer 180, the structure and the thermal properties of the hole injection layer 160 or the hole transport layer 180 that is targeted. For example, a deposition temperature of 100 to 500° C., a vacuum of 10⁻⁸ to 10⁻³ torr, and a deposition speed of 0.01 to 100 Å/sec, may be selected.

The organic light emitting layer 200 may be positioned on the hole transport layer 180. In an exemplary embodiment, the organic light emitting layer 200 may be formed on the hole transport layer 180, which is positioned on the first region I of the substrate 100. Further, the organic light emitting layer 200 may not be formed on the hole transport layer 180 that is positioned on the second region II of the substrate 100. Further, the organic light emitting layer 200 may completely overlap the first electrode 120. Further, an edge of the organic light emitting layer 200 may be positioned on an edge of the pixel-defining film 140.

The organic light emitting layer 200 may emit light of a specific color. Specifically, holes and electrons, which are respectively generated by the first electrode 120 and the second electrode 260 in the organic light emitting layer 200, may be combined to form excitons, and the organic light emitting layer 200 may emit light having a color that corresponds to the energy level that is changed when the excitons shift from an excited state to a ground state.

The organic light emitting layer 200 may include a red organic light emitting layer that emits red light, a green organic light emitting layer that emits green light, and a blue organic light emitting layer that emits blue light. Further, the organic light emitting layer 200 may include a white organic light emitting layer that emits white light.

The red organic layer may be made of a high-molecular or low-molecular organic material, of which the inherent light emitting color is red, or a high-molecular/low-molecular mixed material. In some embodiments, the red organic light emitting layer may include a red host material and a red dopant material. The red host material may be one or more selected from the group including bis(2-(2-hydroxyphenyl)benzothiazolato) zinc (Zn(BTZ)2) and bis-(2-methyl-8-quinolinolate)-4-(phenylphenolate)aluminum, but is not limited thereto. Further, the red dopant material may include Pt0EP, Ir(piq)₃, Btp₂Ir(acac), and DCJTB, but is not limited thereto.

The green organic light emitting layer may be made of a high-molecular or low-molecular organic material, of which the inherent light emitting color is green, or a high-molecular/low-molecular mixed material. In some embodiments, the green organic light emitting layer may include a green host material and a green dopant material. The green host material may be one or more selected from the group including anthracene derivatives and compounds in the carbazole series, but is not limited thereto. As the anthracene derivatives, 9,10-(2-dinaphtyl)anthracene (ADN), or the like, may be used, and as the compounds in the carbazole series, 4,4′-(carbazole-9-i1)biphenyl (CBP), or the like, may be used. Further, the green dopant material may include Ir(ppy)₃ (ppy=phenylpyridine), Ir(ppy)₂(acac), Ir(mpyp)₃, or C545T, but is not limited thereto.

The blue organic light emitting layer may be made of a high-molecular or low-molecular organic material, of which the inherent light emitting color is blue, or a high-molecular/low-molecular mixed material. In some embodiments, the blue organic light emitting layer may include a blue host material and a blue dopant material. Here, the blue host material may be one or more selected from the group including anthracene derivatives and compounds in the carbazole series, but is not limited thereto. Here, as the anthracene derivatives, 9,10-(2-dinaphtyl)anthracene (ADN), and the like, may be used, and as the compounds in the carbazole series, 4,4′-(carbazole-9-i1)biphenyl (CBP), and the like, may be used. Further, the blue dopant material may include F₂Irpic, (F₂ ppy)₂Ir(tmd), Ir(dfppz)₃, or ter-fluorene, but is not limited thereto.

The electron transport layer 220 may be positioned on the organic light emitting layer 200 and the hole transport layer 180. That is, the electron transport layer 220 may be separated by pixels, or may be formed to cover the whole surface of the substrate 100 as illustrated in FIG. 1. That is, the electron transport layer 220 may be a common layer that is commonly formed on the first region I and the second region II.

The electron transport layer 220 may include an electron transport material. The electron transport material may be selected from known electron transport materials. For example, the electron transport material may include at least one of a pyrene series material, a triazine series material, and an anthracene series material, but is not limited thereto. As another example, the electron transport material may include quinoline derivatives, and in particular, tris(8-quinolinolate)aluminum (Alq3), TAZ, or Balq, but is not limited thereto.

The electron transport layer 220 may include not only the above-described electron transport material but also an electron injection material. The electron injection material may be selected from known electron injection materials. For example, the electron injection material may include at least one of LiF, LiQ, and NaQ, but is not limited thereto. As another example, the electron injection material may include NaCl, CsF, Li₂O, or BaO, but is not limited thereto.

One side portion of the electron transport layer 220 that is adjacent to the organic light emitting layer 200 may include a greater amount of the electron injection material than the electron transport material. Further, the other side portion of the electron transport layer 220 that faces the one side portion of the electron transport layer 220 may include a greater amount of the electron transport material than the electron injection material.

The electron transport layer 220 may include a first electron transport layer 220a that is adjacent to the organic light emitting layer 200 and a second electron transport layer 220b that is positioned on the first electron transport layer 220a. In an exemplary embodiment, the volume ratio of the electron transport material to the electron injection material in the first electron transport layer 220a may be about 1:9 to about 5:5, and the volume ratio of the electron transport material to the electron injection material in the second electron transport layer 220b may be about 5:5 to about 9:1. In another exemplary embodiment, the volume ratio of the electron transport material to the electron injection material in the first electron transport layer 220a may be about 3:7 to about 4:6, and the volume ratio of the electron transport material to the electron injection material in the second electron transport layer 220b may be about 7:3 to about 6:4. In still another exemplary embodiment, the volume ratio of the electron transport material to the electron injection material in the first electron transport layer 220a may be about 4:6, and the volume ratio of the electron transport material to the electron injection material in the second electron transport layer 220b may be about 6:4. That is, although the overall volume ratio between the electron transport material and the electron injection material in the electron transport layer 220 may be about 5:5, the volume ratio of the electron transport material to the electron injection material in the first electron transport layer 220a and the volume ratio of the electron transport material to the electron injection material in the second electron transport layer 220b may not be 5:5.

The electron transport layer 220 may be formed by vacuum-depositing the electron transport material and the electron injection material. In an exemplary embodiment, the electron transport layer 220 may be formed by adjusting a speed per unit time, at which the electron transport material is put into a deposition chamber and a speed per unit time, at which the electron injection material is put into the deposition chamber. For example, the first electron transport layer 220a, in which the volume ratio of the electron transport material to the electron injection material is about 4:6, may be formed by putting the electron transport material into the deposition chamber so that the electron transport material is deposited with a thickness of about 4 Å per second, and putting the electron injection material into the deposition chamber so that the electron injection material is deposited with a thickness of about 6 Å per second. Further, the second electron transport layer 220b, in which the volume ratio of the electron transport material to the electron injection material is about 6:4, may be formed by putting the electron transport material into the deposition chamber so that the electron transport material is deposited with a thickness of about 6 Å per second, and putting the electron injection material into the deposition chamber so that the electron injection material is deposited with a thickness of about 4 Å per second.

When the electron transport layer 220 is formed through vacuum deposition, the first electron transport layer 220a and the second electron transport layer 220b may be separately formed in separate vacuum deposition processes. In an exemplary embodiment, the first electron transport layer 220a may be formed in the first deposition chamber, and the second electron transport layer 220b may be formed in the second deposition chamber that is different from the first deposition chamber. In another exemplary embodiment, the first electron transport layer 220a and the second electron transport layer 220b may be formed in the same deposition chamber, and in this case, a process of initializing the deposition chamber may be provided between a process of forming the first electron transport layer 220a and a process of forming the second electron transport layer 220b. However, embodiments are not limited thereto, and the first electron transport layer 220a and the second electron transport layer 220b may be consecutively formed in the same chamber.

Referring to FIGS. 1 and 2, the electronic transport layer 220 may be positioned on the organic light emitting layer 200 provided on the first region I. Specifically, the electron transport layer 220 may come in direct contact with the organic light emitting layer 200 on the first region I, and may not come in direction contact with the hole transport layer 180.

Referring to FIGS. 1 and 3, the electronic transport layer 220 may be positioned on the hole transport layer 180 provided on the second region II. Specifically, the electron transport layer 220 may come in direct contact with the hole transport layer 180. In an exemplary embodiment, the first electron transport layer 220a may come in direct contact with hole transport layer 180 on the second region II. That is, a portion of the electron transport layer 220 that is adjacent to the hole transport layer 180 may include a greater amount of the electron injection material than the electron transport material.

The electron injection layer 240 may be positioned on the electron transport layer 220. That is, the electron injection layer 240 may be separated by pixels, or may be formed to cover the whole surface of the substrate 100 as illustrated in FIG. 1. The electron injection layer 240 may be a common layer that is commonly formed on the first region I and the second region II. In some embodiments, the electron injection layer 240 may be omitted.

The electron injection layer 240 may include an electron injection material. The electron injection material may be selected from known electron injection materials. For example, the electron injection material may include at least one of LiF, LiQ, and NaQ, but is not limited thereto. As another example, the electron injection material may include NaCl, CsF, Li₂O, or BaO, but is not limited thereto. The electron injection layer 240 may include a material that is different from the electron injection material that is included in the electron transport layer 220.

The electron transport layer 220 or the electron injection layer 240 may be formed by various methods, such as a vacuum deposition method and a spin coating method. In the case where the electron transport layer 220 or the electron injection layer 240 are formed with the vacuum deposition method or the spin coating method, the deposition conditions and the coating conditions may differ depending on the compounds used, and in general, may be selected to be substantially the same as the conditions for forming the hole injection layer 160.

The second electrode 260 may be positioned on the electron injection layer 240. In the case where the second electrode 260 is a cathode electrode, it may be made of a conductive material having a low work function. The second electrode 260 may be formed of Ag, Mg, Al, Pt, Pd, Au, Ni, Nd, Ir, Cr, Li, Ca, or a combination thereof.

The cover layer 280 may be positioned on the second electrode 260. The cover layer 280 may protect laminated films below the cover layer 280. The cover layer 280 may be made of an insulating material. A spacer (not illustrated) may be arranged between the second electrode 260 and the cover layer 280. In some embodiments, the cover layer 280 may be omitted. In this case, an encapsulation film that is made of an insulating material may cover the whole structure to protect the structure.

As described above, according to the display device of exemplary embodiments, when one side portion of the electron transport layer 220 that is adjacent to the organic light emitting layer 200 includes a greater amount of the electron injection material than the electron transport material, and the other side portion of the electron transport layer 220 that is adjacent to the second electrode 260 includes a greater amount of the electron transport material than the electron injection material, both the light emitting efficiency and the lifespan requirements of the display device may be satisfied. Specifically, when one side portion of the electron transport layer 220 that is adjacent to the organic light emitting layer 200 includes a greater amount of the electron injection material than the electron transport material, the stability of the display device can be improved, and when the other side portion of the electron transport layer 220 that is adjacent to the second electrode 260 includes a greater amount of the electron transport material than the electron injection material, the electron transport property can be improved. Accordingly, both the light emitting efficiency and the lifespan requirements of the display device can be satisfied. In other words, when one side portion of the electron transport layer 220 that is adjacent to the organic light emitting layer 200 includes a greater amount of the electron injection material than the electron transport material, and the other side portion of the electron transport layer 220 that is adjacent to the second electrode 260 includes a greater amount of the electron transport material than the electron injection material, the light emitting efficiency and the lifespan of the display device may be improved.

Further, according to exemplary embodiments of the display device, electrons or holes may be prevented from moving to a non-light emitting region that does not emit light, and thus the light emitting efficiency and the lifespan of the display device can be increased. If electrons or holes move to the second region II that does not emit light, the quantity of electrons or holes that move to the first region I that emits light may be relatively decreased, and thus the light emitting efficiency and the lifespan of the display device may be decreased. Accordingly, when the one side portion of the electron transport layer 220, which is adjacent to the hole transport layer 180 on the second region II that does not emit light includes a greater amount of the electron injection material than the electron transport material, the stability of the display device may be improved. Thus, the electrons or holes may be prevented from moving to the second region II.

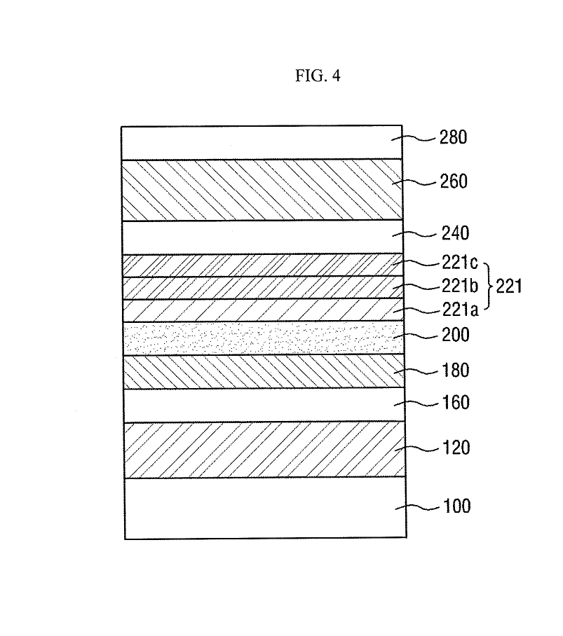

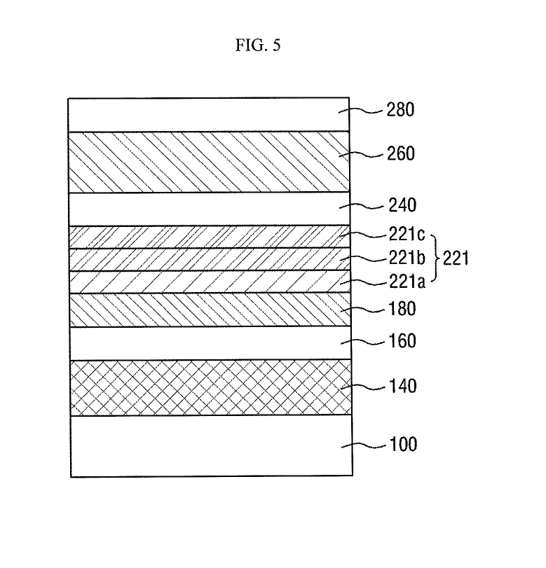

FIG. 4 illustrates an enlarged cross-sectional view of an upper portion of a first region I of a display device according to another embodiment, and FIG. 5 illustrates an enlarged cross-sectional view of an upper portion of a second region II of the display device of FIG. 4. For convenience, the same reference numerals are used for substantially the same elements as the elements illustrated in FIGS. 1 to 3, and duplicate explanations thereof will be omitted.

Referring to FIGS. 4 and 5, an electron transport layer 221 may include a first electron transport layer 221a that is adjacent to the organic light emitting layer 200, a second electronic transport layer 221b positioned on the first electron transport layer 221a, and a third electron transport layer 221c positioned on the second electron transport layer 221b. In an exemplary embodiment, the volume ratio of the electron transport material to the electron injection material in the first electron transport layer 221a may be about 1:9 to about 3:7, the volume ratio of the electron transport material to the electron injection material in the second electron transport layer 221b may be about 3:7 to about 7:3, and the volume ratio of the electron transport material to the electron injection material in the third electron transport layer 221c may be about 7:3 to about 9:1. In another exemplary embodiment, the volume ratio of the electron transport material to the electron injection material in the first electron transport layer 221a may be about 2:8 to about 4:6, the volume ratio of the electron transport material to the electron injection material in the second electron transport layer 221b may be about 4:6 to about 6:4, and the volume ratio of the electron transport material to the electron injection material in the third electron transport layer 221c may be about 6:4 to about 8:2. That is, although the overall volume ratio between the electron transport material and the electron injection material in the electron transport layer 221 may be about 5:5, the volume ratio of the electron transport material to the electron injection material in the first electron transport layer 221a, the volume ratio of the electron transport material to the electron injection material in the second electron transport layer 221b, and the volume ratio of the electron transport material to the electron injection material in the third electron transport layer 221c may not be 5:5.

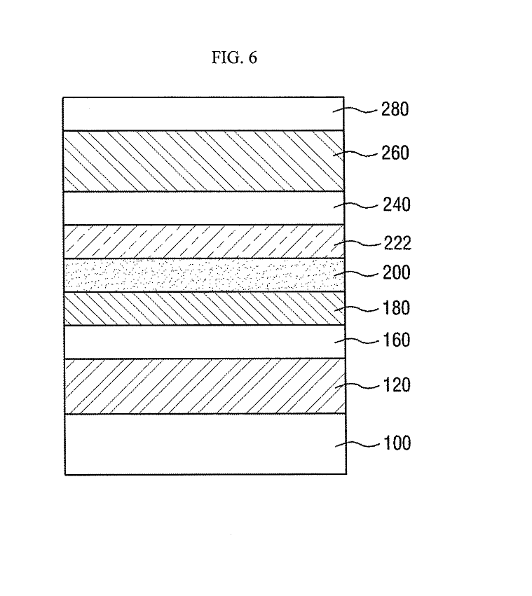

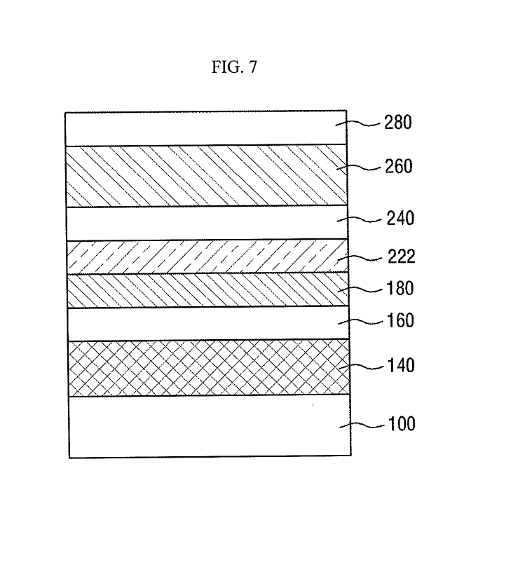

FIG. 6 illustrates an enlarged cross-sectional view of an upper portion of a first region I of a display device according to still another embodiment, and FIG. 7 illustrates an enlarged cross-sectional view of an upper portion of a second region II of the display device of FIG. 6. For convenience, the same reference numerals are used for substantially the same elements as the elements illustrated in FIGS. 1 to 3, and a duplicate explanation thereof is omitted.

Referring to FIGS. 6 and 7, the ratio of the electron injection material to the electron transport material in the electron transport layer 222 may increase in a direction towards the organic light emitting layer 200. In an exemplary embodiment, the ratio of the electron injection material to the electron transport material in the electron transport layer 222 may linearly increase in a direction toward the organic light emitting layer 200. In another exemplary embodiment, the ratio of the electron injection material to the electron transport material in the electron transport layer 222 may increase in steps in a direction toward the organic light emitting layer 200.

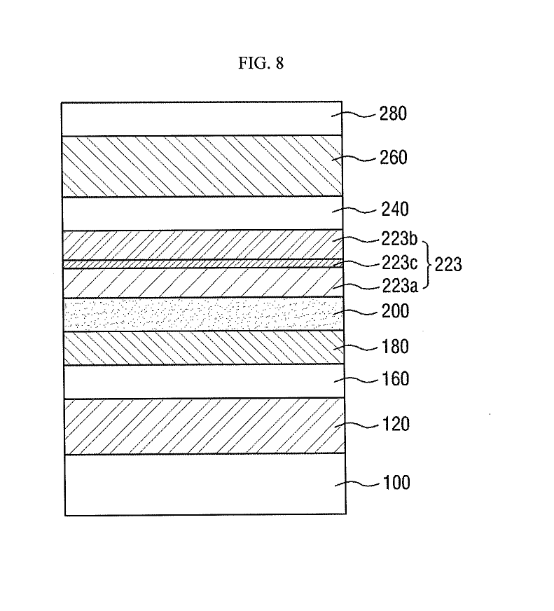

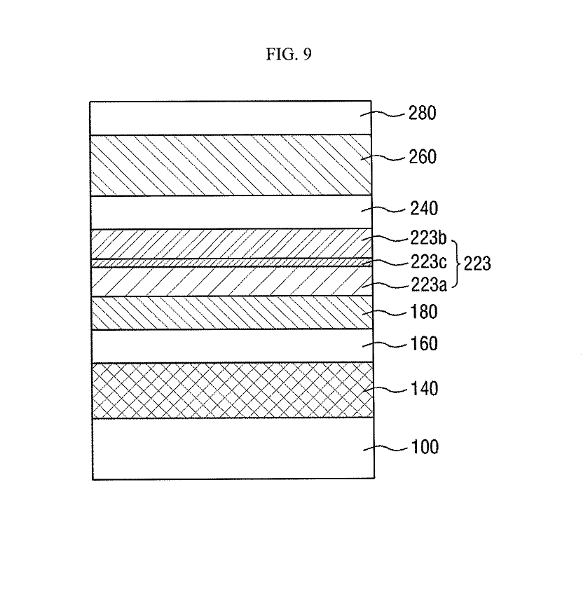

FIG. 8 illustrates an enlarged cross-sectional view of an upper portion of a first region I of a display device according to still another embodiment, and FIG. 9 illustrates an enlarged cross-sectional view of an upper portion of a second region II of the display device of FIG. 8. For convenience, the same reference numerals are used for substantially the same elements as the elements illustrated in FIGS. 1 to 3, and a duplicate explanation thereof is omitted.

Referring to FIGS. 8 and 9, an electron transport layer 223 may include an intermediate layer 223c that is interposed between a first electron transport layer 223a and a second electron transport layer 223b. The intermediate layer 223c may be intentionally formed or may be unintentionally formed when the first electron transport layer 223a and the second electron transport layer 223b are formed in order. In an exemplary embodiment, a ratio of the electron injection material to the electron transport material in the intermediate layer 223c may become higher in a direction towards the organic light emitting layer 200. In an exemplary embodiment, a ratio of the electron injection material to the electron transport material in the entire intermediate layer 223c may be specifically fixed.

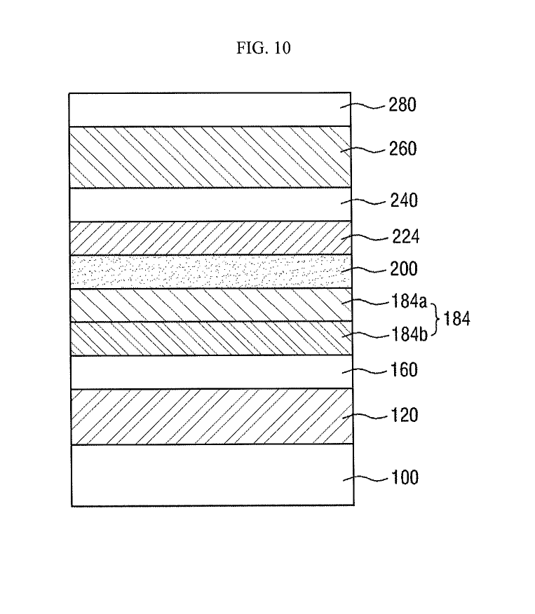

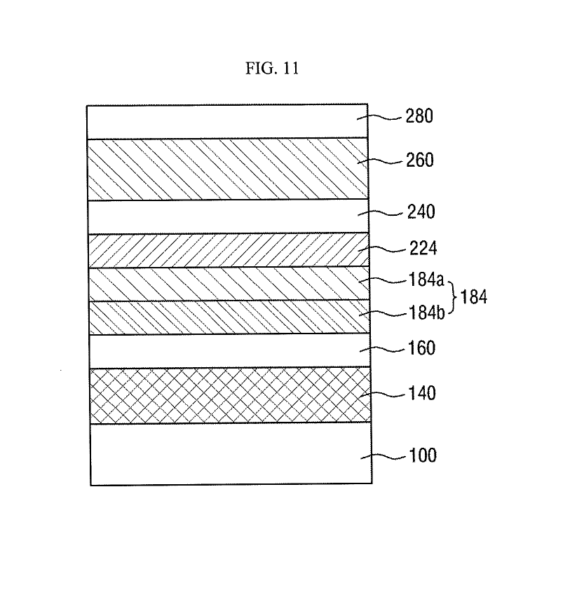

FIG. 10 illustrates an enlarged cross-sectional view of an upper portion of a first region I of a display device according to still another embodiment, and FIG. 11 illustrates an enlarged cross-sectional view of an upper portion of a second region II of the display device of FIG. 10. For convenience, the same reference numerals are used for substantially the same elements as the elements illustrated in FIGS. 1 to 3, and a duplicate explanation thereof is omitted.

Referring to FIGS. 10 and 11, a hole transport layer 184 may include a hole transport material and a hole injection material. That is, the hole transport layer 184 may include not only the hole transport material but also the hole injection material. Further, one side portion of the hole transport layer 184 that is adjacent to the organic light emitting layer 200 may include a greater amount of the hole injection material than the hole transport material, and the other side portion of the hole transport layer 184 that faces the one side portion of the hole transport layer 184 may include a greater amount of the hole transport material than the hole injection material.

The hole transport layer 184 may include a first hole transport layer 184a that is adjacent to the organic light emitting layer 200 and a second hole transport layer 184b that is adjacent to the first electrode 120. In an exemplary embodiment, the volume ratio between the hole transport material and the hole injection material in the first hole transport layer 184a may be about 1:9 to about 5:5, and the volume ratio between the hole transport material and the hole injection material in the second hole transport layer 184b may be about 5:5 to about 9:1. In another exemplary embodiment, the volume ratio between the hole transport material and the hole injection material in the first hole transport layer 184a may be about 3:7 to about 4:6, and the volume ratio between the hole transport material and the hole injection material in the second hole transport layer 184b may be about 7:3 to about 6:4. In still another exemplary embodiment, the volume ratio between the hole transport material and the hole injection material in the first hole transport layer 184a may be about 4:6, and the volume ratio between the hole transport material and the hole injection material in the second hole transport layer 184b may be about 6:4. That is, although the overall volume ratio between the hole transport material and the hole injection material in the hole transport layer 184 may be about 5:5, the volume ratio between the hole transport material and the hole injection material in the first hole transport layer 184a and the volume ratio between the hole transport material and the hole injection material in the second hole transport layer 184b may not be 5:5.

The ratio of the hole injection material to the hole transport material in the hole transport layer 184 may increase in a direction of the organic light emitting layer 200. In an exemplary embodiment, the ratio of the hole injection material to the hole transport material in the hole transport layer 184 may linearly increase in a direction of the organic light emitting layer 200. In another exemplary embodiment, the ratio of the hole injection material to the hole transport material in the hole transport layer 184 may increase in steps in a direction of the organic light emitting layer 200.

The electron transport layer 224 may include only the electron transport material, but is not limited thereto. The electron transport layers 220, 221, 222, and 223 according to the above-described embodiments may be employed.

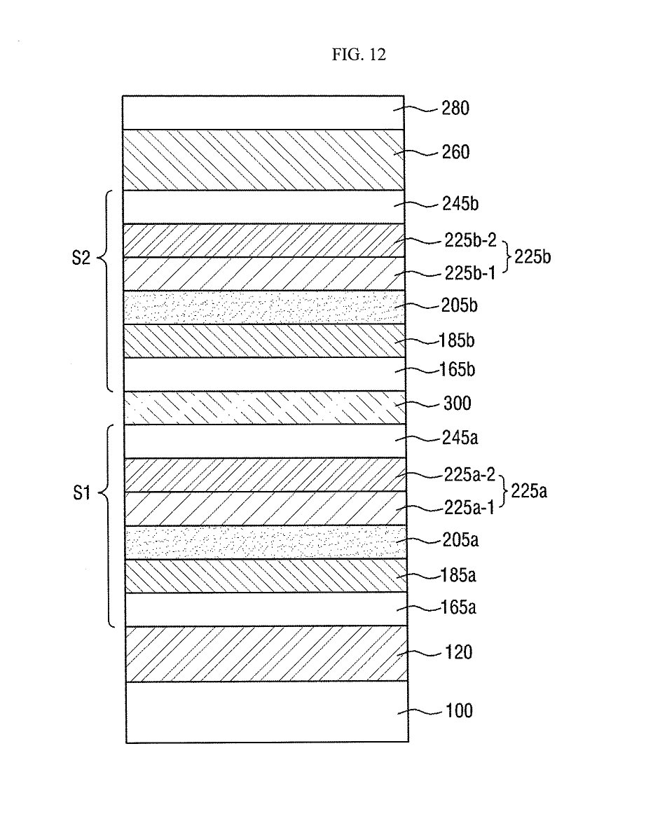

FIG. 12 illustrates an enlarged cross-sectional view of an upper portion of a first region I of a display device according to still another embodiment. For convenience, the same reference numerals are used for substantially the same elements as the elements illustrated in FIGS. 1 to 3, and a duplicate explanation thereof is omitted.

Referring to FIG. 12, a display device according to still another embodiment may be a white organic light emitting display. At least two organic light emitting layers may be laminated on the light emitting region, and light having different wavelengths that is emitted from the at least two organic light emitting layers may be mixed to emit white light.

Specifically, the display device according to still another embodiment may be formed by laminating in order a substrate 100, a first electrode 120, a first hole injection layer 165a, a first hole transport layer 185a, a first organic light emitting layer 205a, a first electron transport layer 225a, a first electron injection layer 245a, a charge generation layer 300, a second hole injection layer 165b, a second hole transport layer 185b, a second organic light emitting layer 205b, a second electron transport layer 225b, a second electron injection layer 245b, a second electrode 260, and a cover layer 280. A first stack S1 between the first electrode 120 and the charge generation layer 300 and a second stack S2 between the charge generation layer 300 and the second electrode 260 may interact with each other to emit white light. In other words, the combination of light emitted from first stack S1 and light emitted from second stack S2 may be white.

One side portion of the first electron transport layer 225a that is adjacent to the first organic light emitting layer 205a and one side portion of the second electron transport layer 225b that is adjacent to the second organic light emitting layer 205b may include a greater amount of the electron injection material than the electron transport material. Specifically, the first electron transport layer 225a may be divided into a lower layer 225a-1 and an upper layer 225a-2, and the lower layer 225a-1 that may include a greater amount of the electron injection material than the electron transport material may be adjacent to the first organic light emitting layer 205a, and the upper layer 225a-2 that may include a greater amount of the electron transport material than the electron injection material may be adjacent to the charge generation layer 300. Further, the second electron transport layer 225b may be divided into a lower layer 225b-1 and an upper layer 225b-2. The lower layer 225b-1 that may include a greater amount of the electron injection material than the electron transport material may be adjacent to the second organic light emitting layer 205b, and the upper layer 225b-2 that may include a greater amount of the electron transport material than the electron injection material may be adjacent to the second electrode 260.

Hereinafter, the light emitting efficiency and the lifespan of the display device according to an embodiment will be described. The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative

### EXAMPLES

### Example 1

First electrode 120 was formed with a thickness of 1000 Å by depositing ITO on a substrate 100 having SiO₂ as a main component by a sputtering method.

A hole injection layer 160 was formed with a thickness of 100 Å by depositing m-MTDATA on the first electrode 120.

A hole transport layer 180 was formed with a thickness of 1200 Å by depositing NPB on the hole injection layer 160.

A blue organic light emitting layer, which included 4,4′-(carbazole-9-i1)biphenyl (CBP) as a blue host material and F₂Irpic as a blue dopant material, was deposited on the hole transport layer 180. Then the blue organic light emitting layer was formed with a thickness of 100 Å.

An electron transport layer 220, which included a first electron transport layer 220a, in which the volume ratio between 9,10-(2-dinaphtyl)anthracene (ADN) and LiF was 4:6, and a second electron transport layer 220b, in which the volume ratio between 9,10-(2-dinaphtyl)anthracene (ADN) and LiF was 6:4, was formed by vacuum-depositing 9,10-(2-dinaphtyl)anthracene (ADN) and LiF on the blue organic light emitting layer. Then the first electron transport layer 220a and the second electron transport layer 220b were respectively formed with a thickness of 150 Å.

An electron injection layer 240 was formed with a thickness of 13 Å by depositing LiF on the electron transport layer 220.

A second electrode 260 was formed with a thickness of 100 Å by depositing MgAg on the electron injection layer 240.

A cover layer 280 was formed with a thickness of 600 Å by depositing SiO₂ on the second electrode 260.

### Comparative Example 1

In the same manner as the Example 1, the electron transport layer was formed with a thickness of 300 Å by depositing only 9,10-(2-dinaphtyl)anthracene (ADN) on the blue organic light emitting layer.

### Comparative Example 2

In the same manner as Example 1, the electron transport layer, in which the volume ratio between 9,10-(2-dinaphtyl)anthracene (ADN) and LiF was 4:6, was formed with a thickness of 300 Å by vacuum-depositing 9,10-(2-dinaphtyl)anthracene (ADN) and LiF on the blue organic light emitting layer.

### Comparative Example 3

In the same manner as Example 1, the electron transport layer, in which the volume ratio between 9,10-(2-dinaphtyl)anthracene (ADN) and LiF was 4:6, was formed with a thickness of 300 Å by vacuum-depositing 9,10-(2-dinaphtyl)anthracene (ADN) and LiF on the blue organic light emitting layer.

### Comparative Example 4

In the same manner as Example 1, the electron transport layer that includes a first electron transport layer, in which the volume ratio between 9,10-(2-dinaphtyl)anthracene (ADN) and LiF was 6:4, and a second electron transport layer, in which the volume ratio between 9,10-(2-dinaphtyl)anthracene (ADN) and LiF was 4:6, was formed by vacuum-depositing 9,10-(2-dinaphtyl)anthracene (ADN) and LiF on the blue organic light emitting layer. Then the first electron transport layer and the second electron transport layer were respectively formed with a thickness of 150 Å.

The light emitting efficiencies and the lifespans of display devices according to the above-described Example and Comparative Examples are shown in Table 1 below:

TABLE 1

| | Drive | | | | 97% Y Drop |
|---|---|---|---|---|---|
| | Voltage | Efficiency | | Converted | Lifespan |
| | [Volts] | [Cd/A] | CIE_Y | Efficiency | (time) |
| Comparative | 3.8 | 3.5 | 0.041 | 86.5 | 32 |
| Example 1 | | | | | |
| Comparative | 5.5 | 4.1 | 0.042 | 98 | 400 |
| Example 2 | | | | | |
| Comparative | 4.0 | 5.7 | 0.043 | 132.3 | 87 |
| Example 3 | | | | | |
| Comparative | 6.0 | 4.1 | 0.042 | 98.2 | 270 |
| Example 4 | | | | | |
| Example 1 | 5.1 | 4.2 | 0.041 | 101.6 | 500 |

As shown in Table 1, above, the display device according to Example 1 satisfied both the light emitting efficiency and the lifespan requirements as compared with the display devices of the Comparative Examples. In other words, Example 1 surprisingly and unexpectedly exhibited a combination of both good light emitting efficiency and good lifespan as compared with Comparative Examples 1-4.

By way of summation and review, as one example of a display device, an organic light emitting display may include an anode electrode, a cathode electrode, and organic films interposed between the anode electrode and the cathode electrode. The organic films may include at least an organic light emitting layer (EML), and may further include a hole injection layer (HIL), a hole transport layer (HTL), an electron transport layer (ETL), and an electron injection layer (EIL). Such an organic light emitting display may generate excitons through reception of holes and electrons from the anode electrode and the cathode electrode, respectively, and emit light of various colors through changing of the energy level of the excitons.

The electron transport layer included in the organic light emitting display may also be included in other display devices. For example, the electron transport layer may be included in an electroluminescent display.

The electron transport layer may be made only of a generally known electron transport material. However, if the electron transport layer is made only of a known electron transport material, the light emitting efficiency and the lifespan of the display device may be reduced.

In order to increase the light emitting efficiency and the lifespan of a display device, an electron transport layer, which includes not only an electron transport material but also an electron injection material, may be used. The electron injection material may be a material that is generally used in electron injection layers. That is, if the electron transport layer, in which the electron transport material and the electron injection material are mixed with a predetermined ratio is used, the light emitting efficiency and the lifespan of the display apparatus may be increased.

However, when using the electron transport layer in which the electron transport material and the electron injection material are mixed with a predetermined ratio, it may be difficult to satisfy both the light emitting efficiency and the lifespan requirements of the display device. That is, if the amount of electron injection material is decreased in the electron transport layer, the light emitting efficiency may be greatly improved, but the lifespan improvement effect may be low. Further, if the amount of electron injection material is increased in the electron transport layer, the light emitting efficiency may be low, but the lifespan improvement effect may be high. As described above, the light emitting efficiency and the lifespan of the display device may be in conflict with each other depending on the relative amount of the electron injection material to the electron transport material in the electron transport layer.

Accordingly, present embodiments provide a display device that can satisfy both the light emitting efficiency and the lifespan requirements of the display device by making relative amounts of an electron injection material and an electron transport material differ from each other depending on their positions in the electron transport layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display device comprising:
a first electrode;
an organic light emitting layer on the first electrode;
a second electrode on the organic light emitting layer; and
an electron transport layer between the organic light emitting layer and the second electrode, and including an electron transport material and an electron injection material,
wherein one side portion of the electron transport layer that is adjacent to the organic light emitting layer includes a greater amount of the electron injection material than the electron transport material.

2. The display device as claimed in claim 1, wherein an other side portion of the electron transport layer that faces the one side portion of the electron transport layer includes a greater amount of the electron transport material than the electron injection material.

3. The display device as claimed in claim 1, wherein:
the electron transport material includes at least one of a pyrene series material, a triazine series material, and an anthracene series material, and
the electron injection material includes at least one of LiF, LiQ, and NaQ.

4. The display device as claimed in claim 1, further comprising an electron injection layer between the electron transport layer and the second electrode, and including the electron injection material.

5. The display device as claimed in claim 1, wherein:
the electron transport layer includes a first electron transport layer that is adjacent to the organic light emitting layer and a second electron transport layer on the first electron transport layer,
a volume ratio between the electron transport material and the electron injection material in the first electron transport layer ranges from about 1:9 to about 5:5, and
a volume ratio between the electron transport material and the electron injection material in the second electron transport layer ranges from about 5:5 to about 9:1.

6. The display device as claimed in claim 5, wherein the electron transport layer includes an intermediate layer between the first electron transport layer and the second electron transport layer, and
a ratio of the electron injection material to the electron transport material in the intermediate layer increases in a direction towards the organic light emitting layer.

7. The display device as claimed in claim 1, wherein:
the electron transport layer includes a first electron transport layer that is adjacent to the organic light emitting layer, a second electron transport layer on the first electron transport layer, and a third transport layer on the second electron transport layer,
a volume ratio between the electron transport material and the electron injection material in the first electron transport layer ranges from about 1:9 to about 3:7,
a volume ratio between the electron transport material and the electron injection material in the second electron transport layer ranges from about 3:7 to about 7:3, and
a volume ratio between the electron transport material and the electron injection material in the third electron transport layer ranges from about 7:3 to 9:1.

8. The display device as claimed in claim 1, wherein a ratio of the electron injection material to the electron transport material in the electron transport layer increases in a direction towards the organic light emitting layer.

9. The display device as claimed in claim 1, wherein:
the organic light emitting layer includes a first organic light emitting layer and a second organic light emitting layer on the first organic light emitting layer,
the electron transport layer includes a first electron transport layer on the first organic light emitting layer and a second electron transport layer on the second organic light emitting layer, and
one side portion of the first electron transport layer that is adjacent to the first organic light emitting layer and one side portion of the second electron transport layer that is adjacent to the second organic light emitting layer each include a greater amount of the electron injection material than the electron transport material.

10. The display device as claimed in claim 9, further comprising a charge generation layer between the first electron transport layer and the second organic light emitting layer.

11. The display device as claimed in claim 1, wherein the electron transport layer is formed by vacuum-depositing the electron transport material and the electron injection material.

12. A display device comprising:
a first electrode;
an organic light emitting layer on the first electrode;
a second electrode on the organic light emitting layer; and
a hole transport layer between the first electrode and the organic light emitting layer, and including a hole transport material and a hole injection material,
wherein one side portion of the hole transport layer that is adjacent to the organic light emitting layer includes a greater amount of the hole injection material than the hole transport material.

13. The display device as claimed in claim 12, wherein an other side portion of the hole transport layer that faces the one side portion of the hole transport layer includes a greater amount of the hole transport material than the hole injection material.

14. The display device as claimed in claim 12, further comprising a hole injection layer between the first electrode and the hole transport layer, and including the hole injection material.

15. The display device as claimed in claim 12, wherein a ratio of the hole injection material to the hole transport material in the hole transport layer increases in a direction towards the organic light emitting layer.

16. A display device comprising:
a substrate including a first region and a second region;
a hole transport layer on the substrate; and
an electron transport layer on the hole transport layer,
wherein:
the electron transport layer includes an electron transport material and an electron injection material, and a portion of the electron transport layer that is adjacent to the hole transport layer includes a greater amount of the electron injection material than the electron transport material,
the hole transport layer and the electron transport layer cover an entire surface of the substrate, and
the hole transport layer and the electron transport layer are in direct contact with each other in the second region and are not in direct contact with each other in the first region.

17. The display device as claimed in claim 16, wherein a portion of the electron transport layer which faces the portion that is adjacent to the hole transport layer includes a greater amount of the electron transport material than the electron injection material.

18. The display device as claimed in claim 16, wherein:
the electron transport material includes at least one of a pyrene series material, a triazine series material, and an anthracene series material, and
the electron injection material includes at least one of LiF, LiQ, and NaQ.

19. The display device as claimed in claim 16, further comprising an organic light emitting layer in the first region between the hole transport layer and the electron transport layer.

20. The display device as claimed in claim 16, further comprising a pixel-defining film in the second region between the substrate and the hole transport layer.
